(19) United States
(12) Patent Application Publication
(10) Pub. No.: US 2009/0133911 A1
(43) Pub. Date: May 28, 2009

(54) RELEASE FILM FOR USE IN MANUFACTURE OF PRINTED CIRCUIT BOARDS

(75) Inventors: Toru Kuki, Kurashiki-shi (JP); Minoru Onodera, Kurashiki-shi (JP); Makoto Asano, Kurashiki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KURARAY CO., LTD., Kurashiki-shi (JP)

(21) Appl. No.: 12/357,619

(22) Filed: Jan. 22, 2009

Related U.S. Application Data
(63) Continuation of application No. PCT/JP2007/000777, filed on Jul. 19, 2007.

(30) Foreign Application Priority Data
Jul. 24, 2006 (JP) 2006-200429

(51) Int. Cl. H05K 1/00; B32B 27/36; B32B 27/32; H05K 3/38

(52) U.S. Cl. 174/258; 428/483; 156/289

(57) ABSTRACT

To provide a release film which is used to avoid adherence between a press hot plate and a printed circuit board or a cover lay film at the time of press work effected to printed circuit boards such as printed wiring boards, flexible printed circuit boards and multilayered printed circuit boards and which has a heat resistance, a releasing property, a non-contamination property, a follow up capability relative to the circuit pattern, an excellent workability during processing and a small environmental impact at the time of disposal, the release film has a shear modulus of 5×10⁵˜10⁷ Pa at a hot press lamination temperature and is formed by overlapping at least one thermoplastic resin layer and at least one metallic layer one above the other.

### FIELD OF THE INVENTION

The present invention relates to a release film, which can be used during formation of a printed circuit board by the use of a hot press, which is excellent in heat resistance, releasing property and non-contamination property and which can easily be disposed of and also to a method of making a printed circuit board with the use of such release film.

### BACKGROUND ART

The release film has hitherto been largely employed in the process of making printed circuit boards such as, for example, printed wiring boards, flexible printed circuit boards or multilayered printed circuit boards, particularly in hot pressing copper foils or copper clad laminates incorporating therein a pre-preg or a film of a kind comprised of a thermotropic liquid crystal polymer capable of forming an optically anisotropic melt phase (which film is hereinafter referred to as a thermotropic liquid crystal polymer film). The release film is also largely employed in the process of making flexible printed circuit boards, particularly in thermally bonding a cover lay film, made of the thermotropic liquid crystal polymer, to the flexible printed circuit boards having circuit patterns with a thermosetting bonding agent with the use of a hot press, to thereby avoid adherence of the cover lay film to a hot press plate.

In recent years, in view of ever-increasing social concerns about environmental issues and safety, not only is the release film required to have a heat resistance enough to withstand heats evolved during the hot pressing and a mold releasing capability from printed circuit boards and press hot plates, but the release film is also required to be of a nature that can easily be disposed of. In addition, in order to increase the yield of products that have been hot pressed, it is considered important for the release film to have a non-contamination property against copper wirings.

For the release film, a fluorine film, a silicone coated polyethylene terephthalate film and a polymethyl pentene film, for example, have been used, which are disclosed in the Japanese Laid-open Patent Publications No. H02-175247 and No. H05-283862.

However, the fluorine films, although excellent in heat resistance and mold releasing capability, have some problems that they are susceptible to insufficient adherence to the cover lay film so much as to result in circuit deformation, are expensive and are hard to burn, when disposed of, accompanied by emission of poisonous gases. On the other hand, the silicone coated polyethylene terephthalate films and the polymethyl pentene films have some problems that migration of silicone or low molecular weight compounds contained in the composition may result in contamination of printed circuit boards, particularly copper wirings, accompanied by reduction in quality.

### DISCLOSURE OF THE INVENTION

In view of the foregoing, the present invention has for its object to provide a release film which is excellent in heat resistance, mold releasing capability and non-contamination property and which can easily be disposed of.

The inventors of the present invention have conducted a series of extensive studies to examine techniques disclosed in the Japanese Laid-open Patent Publications No. H02-175247 and No. H05-283862, quoted above, in an attempt to alleviate the problems and inconveniences discussed hereinbefore. As a result, the inventors have successfully completed the present invention, after having found that a film including at least one thermoplastic resin layer, of which shear modulus of elasticity at a hot press lamination temperature is within the range of 5×10⁵ to 10⁷ Pa, and at least one metallic layer that is overlapped on such at least one thermoplastic resin layer forms a release film excellent in heat resistance, mold releasing capability and non-contamination property.

According to a first aspect of the present invention, there is provided a release film which is used in the process of making a printed circuit board such as, for example, a printed wiring board, a flexible printed circuit board or a multilayered printed circuit board, including a thermotropic liquid crystal polymer film as a base material, particularly in hot pressing a copper foil or copper clad laminates including a thermotropic liquid crystal polymer film as a base material, to avoid adherence of the printed circuit board such as, for example, the printed wiring board, the flexible printed circuit board or the multilayered printed circuit board to a press hot plate, and which comprises overlapping at least one thermoplastic resin layer, of which shear modulus of elasticity at a hot press lamination temperature is within the range of 5×10⁵ to 10⁷ Pa, and at least one metallic layer one above the other.

According to a second aspect of the present invention, there is provided a release film which is used when a cover lay film, made of the thermotropic liquid crystal polymer film, is fusion bonded to the circuit board or is bonded to the circuit board with a thermosetting bonding agent, in the process of making a circuit board such as, for example, a flexible printed circuit board, and which comprises overlapping at least one thermoplastic resin layer, of which shear modulus of elasticity at a hot press lamination temperature is within the range of 5×10⁵ to 10⁷ Pa, and at least one metallic layer, to avoid adherence of the cover lay film to a hot press plate. In the second aspect of the present invention, the circuit board referred to above is not always limited to that including the thermotropic liquid crystal polymer film as a base material, but may be any circuit board well known in the art.

The thermoplastic resin referred to above is preferably employed in the form of a polyolefin resin.

The polyolefin resin referred to above is preferably a polyethylene resin.

The polyethylene resin referred to above is preferably an ultra high molecular weight polyethylene.

The ultra high molecular weight polyethylene referred to above preferably has a viscosity average molecular weight of 1,000,000 or more.

The metallic layer referred to above is preferably a layer of aluminum or stainless steel.

The metallic layer referred to above preferably has a thickness within the range of 1 to 100 μm.

According to a third aspect of the present invention, there is provided a printed circuit board, a flexible printed circuit board, a multilayered printed circuit board and a printed circuit board covered with a cover lay film which can be manufactured with the use of any one of the release films discussed above, or a method of making such printed circuit boards. In the present invention, the term “printed circuit board” referred to hereinbefore and hereinafter is to be construed as encompassing a substrate having a metallic thin layer formed thereon, in which a circuit pattern is not yet formed thereon, and a substrate having a printed circuit formed thereon.

Also according to a fourth aspect of the present invention, there is provided a material for lamination, adapted to be sandwiched between press hot plates for a hot pressing, which material comprises a thermotropic liquid crystal polyester resin film for forming a printed circuit board or a cover lay film, and an ultra high molecular weight polyethylene film combined with a metallic layer, placed above and below the circuit board or the cover lay film to form a release film.

Since the thermoplastic resin layer employed in the release film of the present invention is excellent not only in heat resistance because it has a high thermal decomposition point and a low temperature dependency of the shear modulus of elasticity, but also in mold releasing capability and non-contamination property, for which the release film can be easily and safely disposed of, the release film of the present invention can be suitably employed for avoiding an adhesion of the printed circuit board to the press hot plate in the process of making the printed circuit board, such as the printed wiring board, the flexible printed circuit board or the multilayered printed circuit board, in which the thermotropic liquid crystal polymer film is used as a base material, particularly, when a copper foil or a copper clad laminate employing the thermotropic liquid crystal polymer film as a base material is hot pressed.

Since the thermoplastic resin layer employed in the release film of the present invention is excellent in heat resistance, mold releasing capability and non-contamination property, for which the release film can be easily and safely disposed of, the release film of the present invention can be suitably employed for avoiding an adhesion of the cover lay film to the press hot plate when, in the process of making the flexible printed circuit board employing the thermotropic liquid crystal polymer film as a base material, the cover lay film employing the thermotropic liquid crystal polymer film is bonded by fusion or with a thermosetting bonding agent by means of a hot pressing.

The release film of the present invention is excellent in heat resistance and mechanical characteristic and has a low environmental loading at the time of disposal thereof. Also, the release film of the present invention is effective to prevent reduction of the cushioning property, which is induced as a result of thermal deformation and which has hitherto been encountered with the conventional release film employing a polyolefin resin, by increasing the molecular weight to limit the behavior of molecular chains during melting so that the release film can exhibit an excellent follow-up capability relative to a wiring pattern and/or surface indentations such as, for example, through-holes in the boards. It also has an excellent mold releasing capability and heat resistance comparable to those of the polyolefin resin. As discussed above, the use of the release film of the present invention is effective to increase the yield of products at the time of hot pressing during the manufacture of the printed circuit boards.

The release film of the present invention, due to being provided with the metallic layer, can exhibit an excellent handling capability during mold release and, also, an excellent thermal conductivity and also effective to protect the press hot plate at the time the resin flows.

### BEST MODE FOR CARRYING OUT THE INVENTION

The thermotropic liquid crystal polymer employed in the practice of the present invention as a base material for the printed circuit board or as a cover lay film is not particularly limited to a specific one, but any known thermotropic liquid crystal polyesters and thermotropic liquid crystal polyester amides, which are classified in the following four types shown in parentheses (1) to (4), and their derivatives can be employed. It is, however, to be noted that in order to obtain a polymer that can form an optically anisotropic melt phase, a proper range does nevertheless exist in combination of the various raw material compounds.

(1) Aromatic or aliphatic dihydroxy compounds (See Table 1 below for representative examples thereof.)

TABLE 1
Chemical formulas of the representative examples
of aromatic or aliphatic dihydroxy compounds

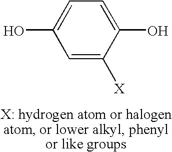

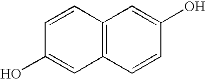

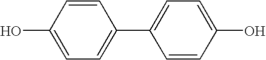

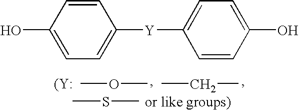

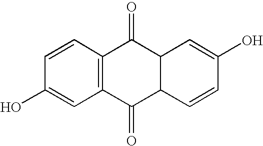

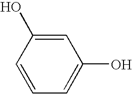

HO(CH₂)nOH
(n: an integer from 2 to 12)

(2) Aromatic or aliphatic dicarboxylic acids (See Table 2 below for representative examples thereof.)

TABLE 2
Chemical formulas of the representative examples
of aromatic or aliphatic dicarboxylic acids

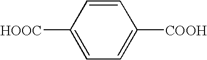

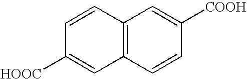

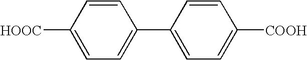

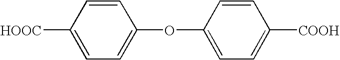

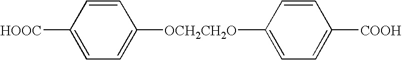

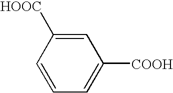

HOOC(CH₂)nCOOH
(n: an integer from 2 to 12)

(3) Aromatic hydroxycarboxylic acids (See Table 3 below for representative examples thereof.)

TABLE 3
Chemical formulas of the representative examples
of aromatic hydroxycarboxylic acids

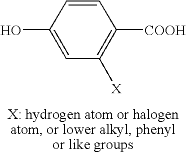

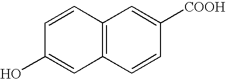

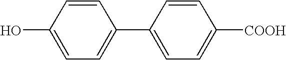

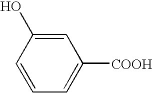

(4) Aromatic diamines, aromatic hydroxyamines and aromatic aminocarboxylic acids (See Table 4 below for representative examples thereof.)

TABLE 4
Chemical formulas of representative examples
aromatic diamines, aromatic hydroxyamines
and aromatic aminocarboxylic acids

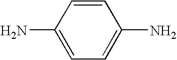

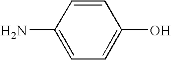

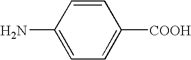

For representative examples of the liquid crystal polymer prepared from any of those starting material compounds, copolymers having such structural units as shown in Table 5 below can be enumerated.

TABLE 5
Examples of thermotropic liquid crystal polymers

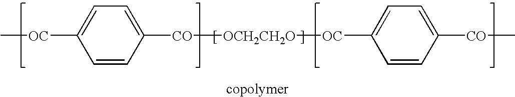

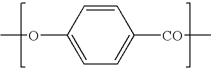

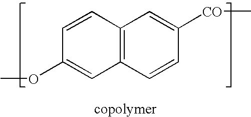

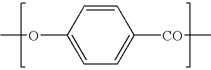

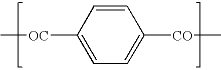

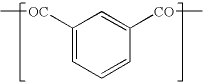

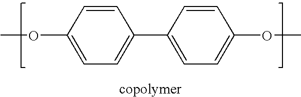

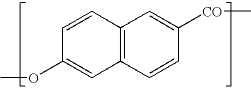

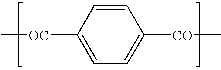

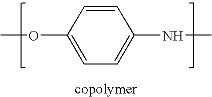

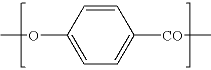

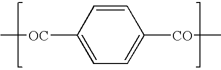

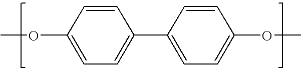

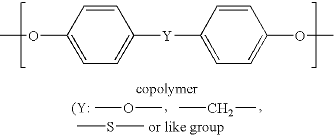

Also, the thermotropic liquid crystal polymer that can be employed in the practice of the present invention is preferably of a kind having a melting point within the range of about 200° C. to about 400° C. and, preferably, within the range of about 250° C. to about 350° C., provided that securement of a desired heat resistance and a desired processability of the film are a matter of importance, but in terms of the film manufacture, the use of the thermotropic liquid crystal polymer having a relatively low melting point is effective to facilitate the manufacture of the film.

The thermotropic liquid crystal polymer film of the present invention can be produced by extrusion-molding of a thermotropic liquid crystal polymer. At this time, although any known extrusion molding method may be employed, any of the known T-die film forming and stretching method, inflation method and the like is industrially advantageously employed therefor. Also, a film obtained by stretching a laminate made up of a film formed from the polymer and a support film can be employed. Particularly with the laminate stretching method and the inflation method, stresses can be applied not only in a direction of the mechanical axis of the film (which direction is hereinafter referred to as “MD direction”), but also in a direction perpendicular to the MD direction (which direction is hereinafter referred to as “TD direction”) and, therefore, it possible to obtain the film, of which mechanical properties and thermal characteristics in both of the MD direction and the TD direction are well balanced with each other.

The thermotropic liquid crystal polymer film employed in the practice of the present invention may have any arbitrarily chosen thickness and may be in the form of a plate or sheet of not greater than 2 mm in thickness. It is however to be noted that where a copper clad laminate utilizing the thermotropic liquid crystal polymer film as an electrically insulating layer is used as a printed circuit board, the thickness of such film is preferably within the range of 20 to 150 μm and, more preferably, within the range of 20 to 50 μm. If the thickness of the film is too small, the rigidity and the strength of the film tend to be lowered to such an extent that deformation may occur under the influence of a pressure, when electronic component parts are surface mounted on the printed circuit board so obtained, accompanied by a reduction in positioning precision which leads to a cause of a defect in the circuit board. Also, as an electrically insulating layer employed in a main circuit board used in, for example, a personal computer, a composite including the thermotropic liquid crystal polymer film and any other electrically insulating material such as, for example, a glass fabric base material can be employed. It is to be noted that the thermotropic liquid crystal polymer film may contain any suitable additives such as, for example, a lubricating agent, an antioxidant and the like.

In the practice of the present invention, where the thermotropic liquid crystal film is used as a cover lay film, when the cover lay film and the printed circuit board are bonded together by the use of a hot press, the hot pressing is carried out at a heat pressing temperature equal to or higher than the melting point of the thermotropic liquid crystal film used in the cover lay film, or the hot press is carried out by applying a thermosetting resin such as, for example, an epoxy resin, to thereby laminate the cover lay film over the printed circuit board.

Material for the resin, which is used as the thermoplastic resin layer forming a part of the release film of the present invention is not specifically limited to a particular one, but may include, for example, a polyolefin resin; a polyphenylene ether resin; a polyphenylene ether resin having a modified functional group; a mixture of a polyphenylene ether resin or a polyphenylene ether resin having a modified functional group with a thermoplastic resin such as, for example, a polystyrene resin which is compatible with a polyphenylene ether resin or a polyphenylene ether resin having a modified functional group; an alicyclic hydrocarbon resin, a thermoplastic polyimide resin, a polyether ether ketone (PEEK) resin, a polyethersulfone resin, a polyamide-imide resin, a polyesterimide resin, a polyester resin, a polystyrene resin, a polyamide resin, a polyvinyl acetal resin, a polyvinyl alcohol resin, a polyvinyl acetate resin, a poly(meta)acrylic ester resin, a polyoxymethylene resin can be enumerated as that material. Of them, the use of the polyolefin resin is preferred because it has a less polarity and can exhibit a good mold releasing capability.

In the practice of the present invention, the resin referred to above is so chosen as to be of a kind having a shear modulus of elasticity at the hot press forming temperature, which is within the range of 5×10⁵ to 10⁷ Pa, and those thermoplastic resins may be formed of a film-like shape and used in a single layer or may be used in a multi-layer structure laminated with one or more films of different material. In order to secure the resin having its shear modulus of elasticity falling within the range specified above, a polymer with a high molecular weight may be used. Also, in order to secure the polymer having a high molecular weight, a length of the polymer chain may be increased, or the formation of a three-dimensional cross-link may be introduced, or the degree of polymerization of the polymer may be increased during polymerization, or an after-treatment such as, for example, electron beam cross-linkage or the like may be carried out subsequent to the polymerization. In the practice of the present invention, the press molding temperature is suitably selected depending on the type of thermotropic liquid crystal polymer, but is so chosen as to be within the range of 260 to 320° C. in consideration of the bondability between films or between the film and the metallic foil.

For the thermoplastic resin referred to above, the use of a polyolefin resin is preferred, and as a monomer forming the polyolefin resin, α-olefines having the number of carbons within the range of 2 to 20 such as, for example, ethylene, propylene, 1-butene, 1-pentene, 4-methyl-1-pentene, 1-hexene, 1-octene, 1-decene and 1-dodecene can be enumerated and one or more of them can be employed to form the polymer. Also, any of those olefin resins may be copolymerized with any other monomers including α,β-unsaturated carboxylic acid esters such as, for example, methyl acrylate, ethyl acrylate, butyl acrylate, 2-ethylhexyl acrylate, cyclohexyl acrylate, methyl methacrylate, ethyl methacrylate, butyl methacrylate, 2-ethylhexyl methacrylate, and cyclohexyl methacrylate; acrylonitrile, methacrylonitrile, acrolein, methacrolein, ethyl vinyl ether, styrene and vinyl acetate. The polyolefin resin referred to above is preferred to have a high molecular weight such that the shear modulus of elasticity can fall within the required range discussed hereinbefore, and for the polyolefin having such a high molecular weight, ultra high molecular weight polyolefin (such as, for example, polyethylene and polypropylene) resins can be enumerated, the molecular weight of which is preferably 1,000,000 or more in terms of viscosity average molecular weight.

Of the polyolefin resins referred to above, the use of polyethylene resin is preferred. The ultra high molecular weight polyethylene resin having a viscosity average molecular weight of 1,000,000 or more and a shear modulus of elasticity at the press molding temperature within the range of 5×10⁵ to 10⁷ Pa is more preferred.

With respect to the reduction in cushioning property resulting from thermal deformation, which has hitherto been considered a problem inherent in the conventional release film of a kind utilizing polyolefin resin having a shear modulus of elasticity lower than that referred to above, the release film of a kind utilizing the ultra high molecular weight polyethylene resin can have a shear modulus of elasticity at the hot press forming temperature that is not lower than 5×10⁵ Pa to thereby sustain the cushioning property, when the behavior of molecular chains during the melting is limited by the increase of the molecular weight, and, accordingly, an excellent follow-up capability relative to the wiring pattern and/or surface indentations such as, for example, through-holes on the board can be realized. Also, it can have an excellent mold releasing capability and an excellent heat resistance both stemming from the polyolefin resin. However, if the storage shear modulus of elasticity at the hot press forming temperature is equal to or higher than 10⁷ Pa, the risk will increase that the circuit pattern will be destructed. Measurement of the limiting viscosity number that is used in calculating the viscosity average molecular weight can be done according to JIS K7367-3: 1999. The shear modulus of elasticity can be obtained by the measurement of the dynamic viscoelasticity and can be measured with the use of a viscoelasticity rheometer.

If required, the thermoplastic resin referred to above may be mixed with an inorganic filling material, fibers, nucleating agents, mold releasing materials, antioxidants (aging retardants) and/or heat stabilizers. Those additives may be employed singly or in combination of two or more of them.

The inorganic filling material referred to above may not be specifically limited and may be employed in the form of, for example, calcium carbonate, titanium oxide, mica, talk, barium sulfate, alumina, silicon oxide or a layered plural hydrate such as hydrotalcite.

The fibers referred to above may not be specifically limited and may be employed in the form of inorganic fibers such as, for example, glass fibers, carbon fibers, boron fibers, silicon carbide fibers or alumina fibers, or organic fibers such as, for example, aramid fibers.

The antioxidant referred to above may not be specifically limited and may be employed in the form of a hindered phenol antioxidant such as, for example, 1,3,5-trimethyl-2,3,6-tris(3,5-di-t-butyl-4-hydroxybenzyl)benzene, 3,9-bis{2-[3-(3-t-butyl-4-hydroxy-5-methyl phenyl)-propionyloxy]-1,1-dimethyl ethyl}-2,4,8,10-tetraoxaspiro{5,5}undecane.

The heat stabilizer referred to above may not be specifically limited and may be employed in the form of, for example, tris(2,4-di-t-butyl phenyl) phosphite, trilauryl phosphite, 2-t-butyl-α-(3-t-butyl-4-hydroxyphenyl)p-cumenyl bis(p-nonylphenyl)phosphite, di-myristyl 3,3′-thiodipropionate, di-stearyl 3,3′-thiodipropionate, pentaerythrityl tetrakis(3-lauryl-thiopropinate) and ditridecyl 3,3′-thiodipropinate.

Material for the metallic layer employed in the practice of the present invention may not be specifically limited and may be employed in the form of, for example, aluminum, stainless steel, copper and silver. Of them, the use of aluminum or stainless steel is preferred because it is economically available. Those materials for the metallic layer may be employed singly or in combination of two or more of them.

To increase the mold releasing property, a silicone mold releasing agent may be applied to a surface of the metallic layer.

The release film of the present invention is of a structure including the thermoplastic resin layer referred to above and the metallic layer overlapped on such thermoplastic resin layer which film is hereinafter referred to as release film (I). The overlap between the thermoplastic resin layer and the metallic layer may not be a mere superimposition or placement of one layer over the other layer, but may be an integration of those two layers. The release film is used in such a manner that one side of the resin layer forming a part of the release film is held in contact with a circuit surface of a printed circuit board such as, for example, a printed wiring board, a flexible printed circuit board or a multilayered printed circuit board whereas one side of the metallic layer is held in contact with a press hot plate. Each of the thermoplastic resin layer and the metallic layer is generally made up of a single layer, but it may be made up of a plurality of layers overlapped one above the other.

The excellent follow-up property can be exhibited when the resin layer of the release film is held in contact with the circuit surface of the circuit board, and a property of removing at a high temperature can be exhibited when the metallic layer thereof is held in contact with the press hot plate, thus resulting in reduction in molding cycle.

The thermoplastic resin layer employed in the release film (I) of the present invention has a surface which is preferably smooth, but such surface may be modified so as to provide an anti-blocking property, a slip property and the like that are required in handling. Also, to facilitate air ventilation during the hot pressing, at least one surface of the release film may have a properly embossed pattern.

The thermoplastic resin layer employed in the release film (I) of the present invention has a thickness preferably within the range of 10 to 300 μm and, more preferably, within the range of 50 to 200 μm. If the thickness of the thermoplastic resin layer is smaller than 10 μm, the cushioning property will be so lowered that the follow-up property will not be exhibited. On the other hand, if the thickness of the thermoplastic resin layer is greater than 500 μm, it is likely to occur that the thermal conductivity during the hot pressing will be lowered.

The metallic layer employed in the release film (I) of the present invention may have a thickness that may not be specifically limited to a particular value, but the thickness thereof is preferably within the range of 1 to 100 μm in consideration of the handling property. If the thickness of the metallic layer is smaller than 1 micrometer, the metallic layer will be susceptible to tear and deformation of the circuit will be apt to occur, but if the thickness of the metallic layer is greater than 100 Mm, it will become inflexible enough to deteriorate the transfer capability and it may occur that the printed circuit board may be broken down.

Manufacture of the thermoplastic resin layer employed in the release film (I) of the present invention may not be specifically limited to a particular method and a skiving method or a melt process, for example, can be employed therefor. The skiving method referred to above may not be specifically limited to a particular one and a method of obtaining a film by molding a cylindrical body and subsequently skiving a side surface of the cylindrical body, for example, can be employed.

The melt process referred to above may not be specifically limited to a particular one and any known method of making a thermoplastic resin film can be employed and, more particularly, an air cooled or water cooled inflation extruding method or a T-die extrusion method, for example, can be employed therefor.

Hereinafter, the details of the present invention will be demonstrated by way of some examples, which are not to be construed as limiting the scope of the present invention. It is to be noted that in the examples and comparative examples that follow, physical properties referred to therein are measured by the following methods.

(1) Shear Modulus of Elasticity:

Using a viscoelasticity rheometer (AR2000, made by and sold from TA Instrument Japan), the shear modulus of elasticity was measured under such conditions that the programming rate was 4° C./min., the frequency was 1 Hz, the strain was 0.1% and the normal stress was 5N.

(2) Resin Flow of Resin Layer of Release Film:

After a round resin film of 50 mm in diameter and 100 μm in thickness was vacuum molded under conditions of 280° C. of press temperature and 2 MPa of press pressure for 60 minutes in press time, the average diameter (four directions) L of the round resin film was measured. Using the following formula (1), the rate of change in dimension was calculated.

Dimension Change Rate (%)=[(L−50)/50]×100 (1)

(3) 90° Peel Strength:

Based on the Peel Strength B Test (90° Directional Peel Strength Test) according to JPCA-BM-O₂, the peel strength was measured by peeling the release film from the circuit board.

(4) Adhesion Property:

Evaluated based on visual observation (to determine the presence or absence of voids)

Accepted: Voids not present.

Rejected: Voids found.

(5) Circuit Deformation:

Evaluated based on visual observation of the circuit on the circuit board that has been hot pressed.

(6) Melting Point:

Using a differential scanning calorimeter, the melting point was obtained by observing the thermal behavior of the film. In other words, the position of the endothermic peak, which appeared when after the thermotropic liquid crystal polymer film had been warmed up at a rate of 10° C. per minute to completely melt, the resultant melt was rapidly cooled down to 50° C. at a rate of 10° C. per minute and was again heated at the rate of 10° C. per minute, was recorded as a melting point.

(7) Mold Releasing Capability between Release Film and Circuit Board:

After the hot press, the peelability between the release film and the circuit board exposed by perforations formed in the cover lay film was evaluated.

### EXAMPLE 1

Using an ultra high molecular weight polyethylene sheet, manufactured by Saxin Corporation of Japan and having a thickness of 100 μm, as the thermoplastic resin layer and aluminum, manufactured by Toyo Aluminium K.K. of Japan and having a thickness of 50 μm, as the metallic layer, the release film (I) was prepared.

The film having a film thickness of 50 μm and a melting point of 280° C. was obtained by means of an inflation film forming method, in which a thermotropic liquid crystal polymer having a melting point of 280° C., which is a copolymer of p-hydroxybenzoic acid and 6-hydroxy-2-naphthoic acid and, was melt extruded and drawn with its draw ratios in longitudinal and transverse directions controlled. The resultant film was then allowed to stand within a hot air dryer of 260° C. for three hours for heat treatment to thereby obtain the film having a melting point of 290° C. Using this resultant film as a base film, copper foils each 18 μm in thickness were set on upper and lower surfaces of the base film and were retained at a press temperature of 290° C. under a press pressure of 4 MPa for a pressing time of 60 minutes, followed by release of the press pressure, when the copper foils with the film intervening therebetween was cooled down to 100° C., to thereby provide a copper clad laminate. Thereafter, a circuit was prepared as a printed wiring according to the test pattern of IPC B-25 to provide a printed circuit board.

The film having a film thickness of 25 μm and a melting point of 280° C. was obtained by means of an inflation molding method, in which a thermotropic liquid crystal polymer, which is a copolymer of p-hydroxybenzoic acid and 6-hydroxy-2-naphthoic acid and having a melting point of 280° C., was melt extruded and drawn with its draw ratios in longitudinal and transverse directions controlled. The resultant film was then perforated at five arbitrarily chosen locations to form perforations of 20 mm in diameter and was used as a cover lay film.

### (Preparation of Flexible Printed Circuit Board)

10 sets, each made up of the release film (I), the cover lay film, the printed circuit board and the release film (I) overlapped one above the other in this order, were arranged on a hot press plate and were vacuum molded to provide a flexible printed circuit board, under a condition that they had been retained at a press temperature of 280° C. under a press pressure of 2 MPa for a pressing time of 60 minutes, and then the press pressure was released when they were cooled down to 100° C., followed by removal of the release films (I).

### EXAMPLE 2

The flexible printed circuit board was prepared in a manner similar to that under Example 1 described above, except that in place of the ultra high molecular weight polyethylene sheet made by and available from Saxin Corporation, an ultra high molecular weight polyethylene sheet of 130 μm in thickness, made by and available from Yodogawa Hu-Tech Co., Ltd., of Japan, was used as the resin layer to form the release film (I).

### COMPARATIVE EXAMPLE 1

The flexible printed circuit board was obtained in a manner similar to that under Example 1 described above, except that in place of the ultra high molecular weight polyethylene sheet made by and available from Saxin Corporation, a high density polyethylene sheet (HDPE) of 100 μm in thickness, made by and available from Okura Industrial Co., Ltd., of Japan, was used as the resin layer to form the release film (I).

### COMPARATIVE EXAMPLE 2

The flexible printed circuit board was obtained in a manner similar to that under Example 1 described above, except that in place of the ultra high molecular weight polyethylene sheet made by and available from Saxin Corporation, Teflon (registered trademark) of 100 μm in thickness, made by and available from Nitto Denko Corporation of Japan, was used as the resin layer to form the release film (I).

### COMPARATIVE EXAMPLE 3

Except that a release film was prepared only with the ultra high molecular weight polyethylene sheet of 100 μm in thickness, made by and available from Saxin Corporation, the flexible printed circuit board was obtained in a manner similar to that under Example 1 described above.

TABLE 6

| | | Examples | | Comparative Examples | | |
|---|---|---|---|---|---|---|
| | | 1 | 2 | 1 | 2 | 3 |
| Resin Layer | Manufacturer | Saxin | Yodokawa | Okura | Nitto | Saxin |
| | Brand | UM-PE | UM-PE | HDPE | TEFLON ® | UM-PE |
| | Thickness | 100 | 130 | 100 | 100 | 100 |
| Metallic Layer | Manufacturer | Toyo Aluminium KK | Toyo Aluminium KK | Toyo Aluminium KK | Toyo Aluminium KK | none |
| | Material | aluminium | aluminium | aluminium | aluminium | none |
| | Thickness | 50 | 50 | 50 | 50 | none |

| | | | | | |
|---|---|---|---|---|---|
| Shear Modulus of Elasticity, 280° C. (Pa) | 1.8 × 10⁶ | 1.8 × 10⁶ | 9.2 × 10⁴ | 1.4 × 10⁸ | 1.8 × 10⁶ |
| Flow of Resin Layer in Release Film (%) | 0 | 0 | 6 | 0 | 0 |
| Peel Strength (N) | 0.02 | 0.02 | 0.02 | 0.02 | 0.02 |
| Adhesion | acceptable | acceptable | acceptable | rejected | acceptable |
| Circuit Deformation | not found | not found | found | found | found |
| Release Between Release Film &Circuit | acceptable | acceptable | acceptable | acceptable | acceptable |
| Board | | | | | |

As can readily be understood from Table 6, neither the problem associated with circuit deformation, which was observed in each of Comparative Examples 1, 2 and 3, nor the problem associated with insufficient adherence of the cover lay film, which was observed in Comparative Example 2, was found in the flexible printed circuit board prepared in each of Examples 1 and 2, in which the ultra high molecular weight polyethylene was used in the resin layer forming a part of the release film (I). Also, the release film (I) exhibited a high peeling characteristic and it has been ascertained that no organic matter tending to contaminate the circuit was deposited.

The release film of the present invention is excellent in heat resistance, mold releasing capability and non-contamination property and can be safely and easily disposed of and is therefore useful as a release film effective to prevent adherence of the printed circuit board to the press hot plate when a copper foil or a copper clad laminate employing the thermotropic liquid crystal polymer film as a base material is hot pressed in the process of manufacture of a printed circuit board such as, for example, a printed wiring board, a flexible printed circuit board or a multilayered printed circuit board, which utilizes the thermotropic liquid crystal polymer film,

Since the release film of the present invention is excellent in heat resistance, mold releasing capability and non-contamination property and can be safely and easily disposed of, the release film of the present invention can be largely employed as a release film for avoiding adherence of the cover lay film to the hot press plate when the cover lay film made of the thermotropic liquid crystal polymer film is bonded by fusion or with a thermosetting bonding agent to the board by means of the hot pressing technique in the course of manufacture of the flexible printed circuit board.

What is claimed is:

1. A release film for use in manufacture of a printed circuit board employing a film comprising a thermotropic liquid crystal polymer capable of forming an optically anisotropic melt phase, as a base material, the release film being inserted in between a press hot plate and the printed circuit board, characterized in that the release film comprises overlapping at least one thermoplastic resin layer, of which shear modulus of elasticity at a hot press lamination temperature is within the range of 5×105 to 107 Pa, and at least one metallic layer one above the other.

2. A release film for use when a cover lay film comprising a thermotropic liquid crystal polymer capable of forming an optically anisotropic melt phase, is bonded by fusion or with a thermosetting bonding agent to a printed circuit board by means of a hot pressing, the release film being inserted in between a press hot plate and the cover lay film, characterized in that the release film comprises overlapping at least one thermoplastic resin layer, of which shear modulus of elasticity at a hot press lamination temperature is within the range of 5×105 to 107 Pa, and at least one metallic layer one above the other.

3. The release film as claimed in claim 1, characterized in that the thermoplastic resin is a polyolefin resin.

4. The release film as claimed in claim 2, characterized in that the thermoplastic resin is a polyolefin resin.

5. The release film as claimed in claims 3, characterized in that the thermoplastic resin is a polyethylene resin.

6. The release film as claimed in claims 4, characterized in that the thermoplastic resin is a polyethylene resin.

7. The release film as claimed in claims 5, characterized in that the thermoplastic resin is an ultra high molecular weight polyethylene resin.

8. The release film as claimed in claims 6, characterized in that the thermoplastic resin is an ultra high molecular weight polyethylene resin.

9. The release film as claimed in claim 7, characterized in that the ultra high molecular weight polyethylene resin has a viscosity average molecular weight of 1,000,000 or more.

10. The release film as claimed in claim 8, characterized in that the ultra high molecular weight polyethylene resin has a viscosity average molecular weight of 1,000,000 or more.

11. The release film as claimed in claim 1, characterized in that the printed circuit board includes a printed wiring board, a flexible printed circuit board and a multilayered printed circuit board.

12. The release film as claimed in claim 2, characterized in that the printed circuit board includes a printed wiring board, a flexible printed circuit board and a multilayered printed circuit board.

13. The release film as claimed in claim 1, characterized in that a metal forming the metallic layer is aluminum or stainless steel.

14. The release film as claimed in claim 2, characterized in that a metal forming the metallic layer is aluminum or stainless steel.

15. The release film as claimed in claim 13, characterized in that the metallic layer has a thickness within the range of 1 μm to 100 μm.

16. The release film as claimed in claim 14, characterized in that the metallic layer has a thickness within the range of 1 μm to 100 μm.

17. A method of making a printed circuit board comprising a process of making a printed circuit board employing a film comprising a thermotropic liquid crystal polymer capable of forming an optically anisotropic melt phase as a base material or a process of bonding a cover lay film comprising such thermotropic liquid crystal polymer to a printed circuit board by fusion or with a thermosetting bonding agent by means of a hot pressing, characterized in that a hot pressing is carried out with use of the release film comprising overlapping a metallic layer and a thermoplastic resin layer having a shear modulus of elasticity at a hot press lamination temperature within the range of 5×105 to 107 Pa one above the other, with the metallic layer held in contact with the press hot plate, and with the circuit board or the cover lay film held in contact with the thermoplastic resin layer.

18. A printed circuit board manufactured with the use of the release film as defined in claim 1.

19. A printed circuit board protected by a cover lay film manufactured with the use of the release film as defined in claim 2.

20. A method of making a printed circuit board characterized by the use of the release film as defined in claim 1.

21. A method of making a printed circuit board protected by a cover lay film, characterized by the use of the release film as defined in claim 2.

22. A material for lamination adapted to be sandwiched between press hot plates for a hot pressing, comprising:
a film of thermotropic liquid crystal polyester resin for forming a printed circuit board or a cover lay film; and
a film of ultra high molecular weight polyethylene for forming a release film in combination with a metallic layer placed on upper and lower surfaces of the circuit board or cover lay film so as to sandwich the printed circuit board or the cover lay film.
